(19) United States
(12) Patent Application Publication
(10) Pub. No.: US 2025/0176299 A1
(43) Pub. Date: May 29, 2025

(54) ELECTRONIC DEVICE, ELECTRONIC COMPONENT, METHOD FOR MANUFACTURING ELECTRONIC DEVICE, AND METHOD FOR MANUFACTURING ELECTRONIC COMPONENT

(71) Applicant: CANON KABUSHIKI KAISHA, Tokyo (JP)

(72) Inventor: HIDEMASA OSHIGE, Kanagawa (JP)

(21) Appl. No.: 18/928,906

(22) Filed: Oct. 28, 2024

(30) Foreign Application Priority Data
Nov. 24, 2023 (JP) 2023-199494

(51) Int. Cl. H01L 27/146; H01L 21/66

(52) U.S. Cl. CPC H10F 39/809; H01L 22/14; H10F 39/018; H10F 39/026; H10F 39/811

(57) ABSTRACT

A method for manufacturing an electronic device includes a first chip preparing step, a second chip preparing step, and a fixing step. The first chip preparing step is a step of preparing a first chip in which a first semiconductor element, a first insulating layer, a first wiring layer, and a first connection electrode are provided on a side of a first main surface, and a terminal electrically connected to the first wiring layer is exposed to a side opposite to the first main surface. The second chip preparing step is a step of preparing a second chip in which a second semiconductor element, a second insulating layer, a second wiring layer, and a second connection electrode are provided on a side of a second main surface of a second substrate. The fixing step is a step of fixing the first chip and the second chip.

### BACKGROUND OF THE INVENTION

### Field of the Invention

The present invention relates to an electronic device (semiconductor apparatus) in which a plurality of chips each including a semiconductor element are integrated, and the like.

### Description of the Related Art

In recent years, a plurality of chips in which a semiconductor element is provided are stacked in order to achieve size reduction and improvement in performance of an electronic device. A test terminal for inspecting an electrical characteristic may be provided in an electronic device in which a plurality of chips is stacked.

JP 2015-46569 A discloses a method for arranging a test terminal in an electronic device in which two chips are stacked.

JP 2015-46569 A describes a method for arranging a test pad in a semiconductor apparatus in which a surface of one semiconductor chip on which a semiconductor element is formed is bonded to a surface of the other semiconductor chip on which no semiconductor element is formed. According to the method for arranging a test pad disclosed in JP 2015-46569 A, it is possible to inspect a chip by using a wafer tester, and thus it is not necessary to use a dedicated tester. However, in JP 2015-46569 A, a method for arranging a test pad has not been studied for a semiconductor apparatus formed by bonding surfaces of both chips on which semiconductor elements are formed.

Therefore, there has been a demand for a technology capable of suppressing an increase in size of an electronic device (semiconductor apparatus) while installing a test terminal for evaluating an electrical characteristic for the electronic device (semiconductor apparatus) formed by bonding surfaces of respective chips on which semiconductor elements are formed.

### SUMMARY OF THE INVENTION

According to a first aspect of the present invention, an electronic device includes a first chip in which a first semiconductor element, a first insulating layer, a first wiring layer, and a first connection electrode formed in a layer different from the first wiring layer are provided on a side of a first main surface of a first substrate, and a second chip in which a second semiconductor element, a second insulating layer, a second wiring layer, and a second connection electrode formed in a layer different from the second wiring layer are provided on a side of a second main surface of a second substrate. The first chip and the second chip are fixed such that the first main surface and the second main surface face each other with the first insulating layer, the first wiring layer, the first connection electrode, the second insulating layer, the second wiring layer, and the second connection electrode interposed therebetween, and the first connection electrode and the second connection electrode are electrically connected. The first chip includes a terminal electrically connected to the first wiring layer and exposed to a side opposite to the second chip. A projected area of the first chip is smaller than a projected area of the second chip, and the first chip is included in the second chip in plan view in a case where viewed from a direction perpendicular to the first main surface.

According to a second aspect of the present invention, a method for manufacturing an electronic device includes a first chip preparing step, a second chip preparing step, and a fixing step. The first chip preparing step is a step of preparing a first chip in which a first semiconductor element, a first insulating layer, a first wiring layer, and a first connection electrode formed in a layer different from the first wiring layer are provided on a side of a first main surface of a first substrate, and a terminal electrically connected to the first wiring layer is exposed to a side opposite to the first main surface. The second chip preparing step is a step of preparing a second chip in which a second semiconductor element, a second insulating layer, a second wiring layer, and a second connection electrode formed in a layer different from the second wiring layer are provided on a side of a second main surface of a second substrate. The fixing step is a step of fixing the first chip and the second chip such that the first main surface and the second main surface face each other with the first insulating layer, the first wiring layer, the first connection electrode, the second insulating layer, the second wiring layer, and the second connection electrode interposed therebetween, the first connection electrode and the second connection electrode are electrically connected, and a projected area of the first chip is smaller than a projected area of the second chip, and the first chip is included in the second chip in plan view in a case where viewed from a direction perpendicular to the first main surface.

Further features of the present invention will become apparent from the following description of exemplary embodiments with reference to the attached drawings.

### BRIEF DESCRIPTION OF THE DRAWINGS

FIG. 1A is a schematic plan view of an electronic device according to an embodiment.

FIG. 1B is a schematic cross-sectional view of the electronic device taken along line A-A illustrated in FIG. 1A.

FIG. 1C is a schematic cross-sectional view of an electronic component according to an embodiment.

FIG. 2A is a schematic cross-sectional view of a first chip.

FIG. 2B is a schematic cross-sectional view of a second chip.

FIG. 3A is a view illustrating a process of manufacturing the first chip.

FIG. 3B is a view illustrating a process of manufacturing the first chip following FIG. 3A.

FIG. 3C is a view illustrating a process of manufacturing the first chip following FIG. 3B.

FIG. 3D is a view illustrating a process of manufacturing the first chip following FIG. 3C.

FIG. 3E is a view illustrating a process of manufacturing the first chip following FIG. 3D.

FIG. 4A is a view illustrating a process of manufacturing the second chip.

FIG. 4B is a view illustrating a process of manufacturing the second chip following FIG. 4A.

FIG. 4C is a view illustrating a process of manufacturing the second chip following FIG. 4B.

FIG. 4D is a view illustrating a process of manufacturing the second chip following FIG. 4C.

FIG. 5A is a view illustrating a process of manufacturing the electronic device.

FIG. 5B is a view illustrating a process of manufacturing the electronic device following FIG. 5A.

FIG. 5C is a view illustrating a process of manufacturing the electronic device following FIG. 5B.

FIG. 5D is a view illustrating a process of manufacturing the electronic device following FIG. 5C.

FIG. 6A is a view illustrating a state in which an electrical characteristic of the electronic device is evaluated.

FIG. 6B is a view illustrating an electronic component according to a first embodiment.

FIG. 7 is a plan view illustrating a state in which a plurality of electronic devices is formed on a wafer.

FIG. 8A is a schematic cross-sectional view of an electronic device according to a second embodiment.

FIG. 8B is a view illustrating an electronic component according to the second embodiment.

FIG. 9A is a schematic diagram for describing equipment according to a third embodiment.

FIG. 9B is a schematic diagram illustrating an example of a photoelectric conversion system according to the third embodiment.

FIG. 9C is a schematic diagram illustrating an example of an in-vehicle photoelectric conversion system according to the third embodiment.

### DESCRIPTION OF THE EMBODIMENTS

An electronic device (semiconductor apparatus), a method for manufacturing the electronic device (semiconductor apparatus), and the like according to embodiments of the present invention will be described with reference to the drawings. The embodiments described below are merely examples, and for example, detailed configurations can be appropriately changed and implemented by those skilled in the art without departing from the gist of the present invention.

In the drawings referred to in the following description of the embodiments, elements denoted by the same reference signs have the same functions unless otherwise specified. In the drawings, in a case where a plurality of the same elements is arranged, reference signs and a description thereof may be omitted.

In addition, the drawings may be schematic for convenience of illustration and description, and thus, the shape, size, arrangement, and the like of elements in the drawings may not strictly match those of actual ones.

### First Embodiment

### Configuration

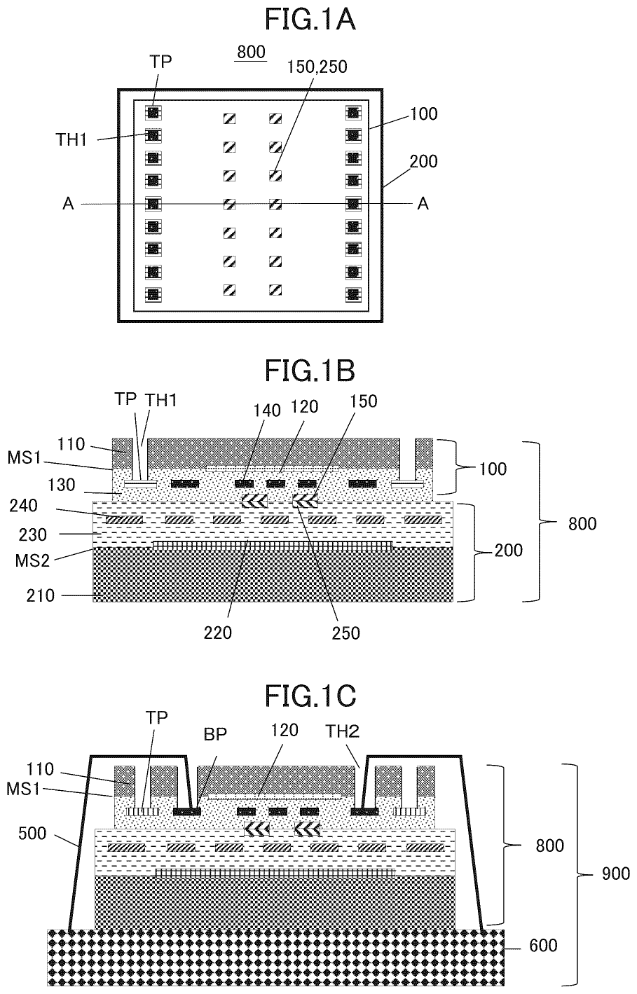

FIG. 1A is a schematic plan view illustrating an electronic device 800 serving as an electronic device (semiconductor apparatus) according to the present embodiment. FIG. 1A is a view of the electronic device 800 when viewed from a direction perpendicular to a main surface thereof (a normal direction of the main surface), and schematically illustrates not only an appearance but also positions of a first connection electrode 150 and a second connection electrode 250 provided inside the device. FIG. 1B is a schematic cross-sectional view of the electronic device 800 taken along line A-A illustrated in FIG. 1A.

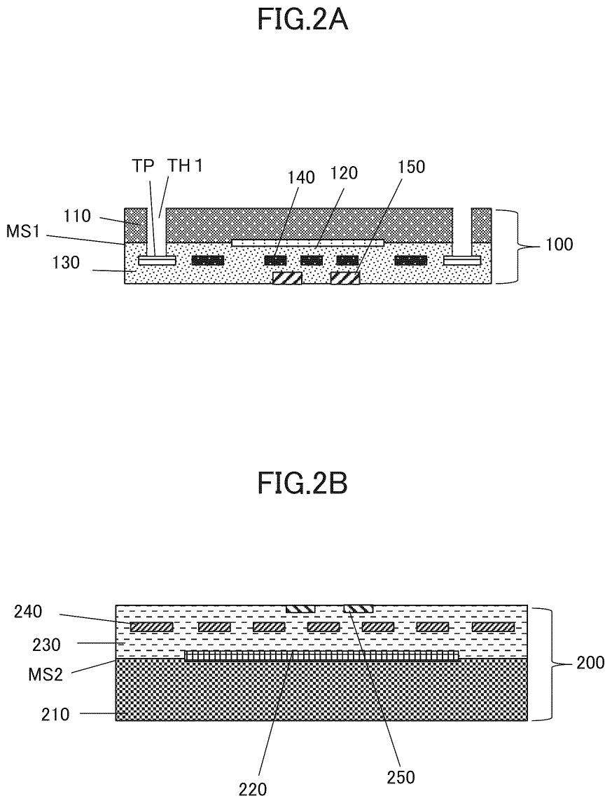

As illustrated, the electronic device 800 has a configuration in which a first chip 100 and a second chip 200 are integrated. FIG. 2A illustrates a schematic cross-sectional view of the first chip 100, and FIG. 2B illustrates a schematic cross-sectional view of the second chip 200.

As illustrated in FIG. 2A, the first chip 100 includes a first substrate 110 that is, for example, a semiconductor substrate. A semiconductor element 120 is formed on a side of a first main surface MS1 of the first substrate 110. Although schematically illustrated in the drawings, the semiconductor element 120 may include, for example, a large number of transistors and diodes.

A first insulating layer 130, a first wiring layer 140, a test terminal TP, and the first connection electrode 150 are further provided on the side of the first main surface MS1 of the first substrate 110. The first wiring layer 140, the test terminal TP, and the first connection electrode 150 are formed using, for example, aluminum or copper.

Although the first wiring layer 140 is schematically illustrated as a single layer in the drawing, the first wiring layer 140 may have a multilayer wiring structure in which a plurality of wiring layers is stacked. For example, in the first insulating layer 130, silicon oxide, silicon nitride, silicon oxynitride, silicon carbide, or the like is used and can function as an interlayer insulating layer in the multilayer wiring structure. The multilayer wiring structure may include vias and plugs that connect wiring of different layers. In a case where the first wiring layer 140 has the multilayer wiring structure, the test terminal TP is preferably provided in the same layer as any one of multiple wiring layers, or may be provided in a different layer in some cases.

The semiconductor element 120, the first wiring layer 140, and the first connection electrode 150 are electrically connected to form an electronic circuit. The first connection electrode 150 is formed in a layer different from the first wiring layer 140, is exposed on the surface of the first chip 100, and is electrically connected to the second connection electrode 250 provided on the second chip 200 as described below.

The first chip 100 is provided with a through hole TH1 penetrating through the first substrate 110. The through hole TH1 extends into the first insulating layer 130 to expose the test terminal TP. In the present specification, it is assumed that the inside of the through hole is not subjected to conductive treatment unless otherwise specified.

As illustrated in FIG. 2B, the second chip 200 includes a second substrate 210 that is, for example, a semiconductor substrate. A semiconductor element 220 is formed on a side of a second main surface MS2 of the second substrate 210. Although schematically illustrated in the drawings, the semiconductor element 220 may include, for example, a large number of transistors and diodes.

A second insulating layer 230, a second wiring layer 240, and a second connection electrode 250 are further provided on the side of the second main surface MS2 of the second substrate 210. The second wiring layer 240 and the second connection electrode 250 are formed using, for example, aluminum or copper. Although the second wiring layer 240 is schematically illustrated as a single layer in the drawing, the second wiring layer 240 may have a multilayer wiring structure in which a plurality of wiring layers is stacked. For example, in the second insulating layer 230, silicon oxide, silicon nitride, silicon oxynitride, silicon carbide, or the like is used and can function as an interlayer insulating layer in the multilayer wiring structure. The multilayer wiring structure may include vias and plugs that connect wiring of different layers.

The semiconductor element 220, the second wiring layer 240, and the second connection electrode 250 are electrically connected to form an electronic circuit. The second connection electrode 250 is formed in a layer different from the second wiring layer 240, is exposed on the surface of the second chip 200, and is electrically connected to the first connection electrode 150 provided on the first chip 100 as described below.

Returning to FIG. 1B, in the electronic device 800, the first chip 100 and the second chip 200 are integrated such that the semiconductor element 120 of the first chip 100 and the semiconductor element 220 of the second chip 200 face each other with an insulating layer and a wiring layer interposed therebetween. That is, the first chip and the second chip are fixed such that the first main surface MS1 and the second main surface MS2 face each other with the first insulating layer, the first wiring layer, the first connection electrode, the second insulating layer, the second wiring layer, and the second connection electrode interposed therebetween, and the first connection electrode and the second connection electrode are electrically connected.

When the first chip and the second chip are fixed, the first connection electrode 150 and the second connection electrode 250 can be mechanically and electrically bonded by thermocompression bonding without an adhesive or the like interposed therebetween. In addition, the first insulating layer 130 and the second insulating layer 230 can be directly bonded at a low temperature by forming the first insulating layer 130 and the second insulating layer 230 using the same material and activating the respective surfaces by a method such as plasma irradiation.

Here, in order to evaluate an electrical characteristic of the chip, a method of accessing the test terminal TP with a probe of a tester will be considered. For example, a method of forming a hole in the first insulating layer 130 from a side of a contact surface between the first chip 100 and the second chip 200 to access the test terminal TP instead of accessing the test terminal TP through the through hole TH1 penetrating through the first substrate 110 as in the present embodiment will be considered. In this case, both the chips are arranged such that at least a part of the first chip 100 protrudes beyond an outer edge of the second chip 200 in plan view, and a hole needs to be formed in the first insulating layer 130 such that the test terminal TP can be accessed at the protruding portion. Then, the electronic device increases in size by the amount by which the first chip 100 protrudes beyond the outer edge of the second chip 200, and cost also increases by the amount by which an area of the substrate increases.

On the other hand, in the electronic device 800 according to the present embodiment, as illustrated in FIG. 1A, a projected area of the first chip 100 in which the test terminal TP is provided can be made smaller than a projected area of the second chip 200 in plan view, so that the cost of the substrate can be reduced. Moreover, the first chip 100 is included in the second chip 200 in plan view, and both chips are arranged such that the first chip 100 does not protrude beyond the outer edge of the second chip 200. In the electronic device 800 according to the present embodiment, the test terminal TP can be accessed through the through hole TH1 from a side opposite to the main surface MS1 (a main surface on a side on which the semiconductor element 120 is provided) of the first substrate 110. As described above, according to the present embodiment, when the first chip 100 including the test terminal TP and the second chip 200 are arranged and integrated such that the semiconductor elements face each other, size reduction of the electronic device 800 can be achieved.

FIG. 1C illustrates a schematic cross-sectional view of an electronic component 900 according to an embodiment. The electronic component 900 includes a circuit board 600 and an electronic device 800 mounted on the circuit board 600. The circuit board 600 can be, for example, any of a rigid board such as a glass epoxy board or a ceramic board, a flexible board such as a flexible printed board, and a rigid flexible board obtained by combining the rigid board and the flexible board.

The electronic device 800 used in the present embodiment is different from the electronic device 800 illustrated in FIG. 1B in that an external connection terminal BP electrically connected to a first wiring layer 140 is provided in a first chip 100. Similarly to a test terminal TP, the external connection terminal BP is exposed so as to be accessible from a side opposite to a main surface MS1 of a first substrate 110 (a main surface on a side on which a semiconductor element 120 is provided). That is, the first chip 100 is provided with a through hole TH2 penetrating through the first substrate 110, and the through hole TH2 extends into a first insulating layer 130 to expose the external connection terminal BP.

In the electronic component 900, the external connection terminal BP is electrically connected to the circuit board 600 by a connection member 500. As the connection member 500, for example, a conductive wire made of gold, copper, aluminum or the like is used, and the external connection terminal BP and the circuit board 600 are connected by a general wire bonding method. In this example, the external connection terminal BP is provided separately from the test terminal TP, but the test terminal TP may also function as the external connection terminal BP.

In the electronic component 900 according to the present embodiment, the test terminal TP and the external connection terminal BP can be accessed through the through hole TH1 and the through hole TH2 from the side opposite to the main surface MS1 (the main surface on the side on which the semiconductor element 120 is provided) of the first substrate 110. As described above, according to the present embodiment, when the first chip 100 including the test terminal TP and the external connection terminal BP and a second chip 200 are arranged and integrated such that the semiconductor elements face each other, size reduction of the electronic device 800 and the electronic component 900 can be achieved.

As the components of the electronic device 800 and the electronic component 900 according to the present embodiment, the first chip 100 is an image sensor, and the second chip 200 is a chip including at least one of a memory circuit and a logic circuit. Alternatively, the first chip 100 is a memory chip, and the second chip 200 is a logic chip. The above configuration is an example, and other types of chips may be combined to form the electronic device (semiconductor apparatus) or the electronic component according to the embodiment.

### Manufacturing Method

Methods for manufacturing the electronic device and the electronic component according to the present embodiment will be described with reference to the drawings. Here, a case where the same terminal TM performs functions of a test terminal for determining whether the first chip is good or bad, a test terminal for determining whether the electronic device is good or bad, and an external connection terminal for connecting the electronic device to the circuit board will be described as an example. It goes without saying that each function may be performed by a separate terminal.

### Method for Manufacturing First Chip

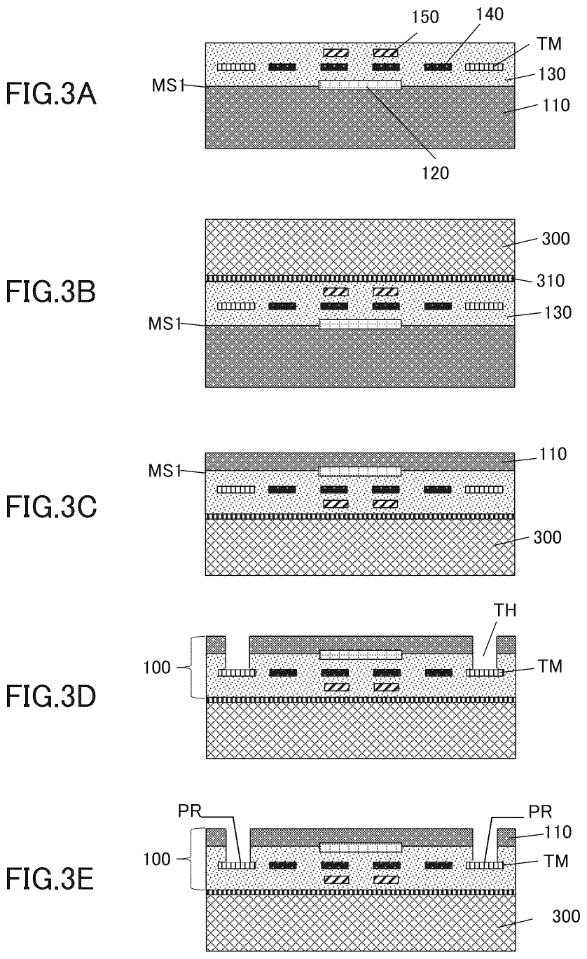

First, a method for manufacturing the first chip 100 (first chip preparing step) will be described with reference to FIGS. 3A to 3E. Each drawing illustrates a schematic cross section of the first chip 100 at each stage of the manufacturing process. Although only a single first chip 100 is illustrated in FIGS. 3A to 3E, it is also possible to form a plurality of first chips 100 on the same wafer and cut the same wafer later.

First, as illustrated in FIG. 3A, the semiconductor element 120, the first insulating layer 130, the first wiring layer 140, the terminal TM, and the first connection electrode 150 are sequentially formed on the main surface MS1 (first main surface) of the first substrate 110. As the first substrate 110, for example, a single crystal semiconductor substrate such as silicon substrate can be used.

The first semiconductor element 120 such as a transistor or a diode is provided on the main surface MS1 which is one main surface of the first substrate 110. When an insulator substrate such as glass or resin is used for the first substrate 110 without using a semiconductor substrate, a thin film transistor (TFT) may be provided as the first semiconductor element 120 on the main surface MS1 of the insulator substrate.

The first insulating layer 130 is provided on the first semiconductor element 120 and on the main surface MS1 on which the first semiconductor element 120 is not provided. As the first insulating layer 130, for example, silicon oxide, silicon nitride, silicon oxynitride, silicon carbide, or the like is used. A contact plug (not illustrated) electrically connected to the first semiconductor element 120 is disposed in the first insulating layer 130. A conductive material such as tungsten is embedded in the contact plug. The first wiring layer 140 electrically connected to the first semiconductor element 120 via the contact plug is provided inside the first insulating layer 130.

Although the first wiring layer 140 is schematically illustrated as a single layer in the drawing, the first wiring layer 140 may have a multilayer wiring structure in which a plurality of wiring layers is stacked. The first insulating layer 130 can function as an interlayer insulating layer in the multilayer wiring structure. The multilayer wiring structure may include vias and plugs that connect wiring of different layers. A metal material such as aluminum or copper is used for the first wiring layer 140, and a barrier metal such as Ti, Ta, TiN, or TaN may be provided at an interface between the first wiring layer 140 and the first insulating layer 130 in order to suppress diffusion of metal into the first insulating layer 130.

The terminal TM is preferably formed of the same material in the same layer as any one of multiple wiring layers forming the first wiring layer 140 from the viewpoint of reducing the processes. The first insulating layer 130, the first connection electrode 150, and the first insulating layer 130 are sequentially stacked and provided on the first wiring layer 140 and the terminal TM. At least three layers of a layer between the first semiconductor element 120 and the first wiring layer 140, a layer between the first wiring layer 140 and the first connection electrode 150, and a layer on the first connection electrode 150 are arranged as the insulating layers, but for convenience of illustration, the layers are not distinguished and are illustrated as the first insulating layer 130.

The semiconductor element 120, the first wiring layer 140, and the first connection electrode 150 are electrically connected to form an electronic circuit. A dummy pattern that is not electrically connected to a circuit may be formed in the same layer as the first connection electrode 150, and the dummy pattern may be used as an anchor for enhancing a bonding strength when the first chip 100 and the second chip 200 are bonded.

Next, as illustrated in FIG. 3B, a first carrier substrate 300 is bonded onto the first insulating layer 130 via a first temporary bonding layer 310. As the first temporary bonding layer 310, a heat-release type adhesive whose adhesion strength is reduced by heating can be used. In a case where a light-transmissive substrate is used as the first carrier substrate 300, a UV-release type adhesive whose adhesion strength is reduced by irradiation with ultraviolet rays may be used as the first temporary bonding layer 310. As the first carrier substrate 300, for example, a single crystal semiconductor substrate such as silicon, an insulating substrate such as glass or ceramic, or a metal substrate can be used.

Next, as illustrated in FIG. 3C, a surface of the first substrate 110 opposite to the main surface MS1 is polished by back grinding or CMP to reduce a thickness of the first substrate 110 to a thickness of about 50 μm to 200 μm. In FIG. 3C and subsequent drawings, the orientation is inverted vertically compared to FIGS. 3A and 3B.

Next, as illustrated in FIG. 3D, the through hole TH penetrating through the first substrate 110 is formed from the surface of the first substrate 110 that is opposite to the main surface MS1, and the through hole TH further extends to a part of the first insulating layer 130 to expose the terminal TM. Specifically, when the first substrate 110 is a silicon substrate, a through hole can be formed in the silicon substrate by dry etching using the Bosch method. After the through hole TH is formed in the first substrate 110, the first insulating layer 130 between the first substrate 110 and the terminal TM is removed by reactive ion etching (RIE) to extend the through hole TH, thereby exposing the surface of the terminal TM.

Next, as illustrated in FIG. 3E, a probe PR of the tester is inserted into a hole where the terminal TM is exposed at the bottom, and is brought into contact with the terminal TM to evaluate electrical performance of the first chip 100. The first chip 100 that is a non-defective product is selected based on the electrical performance evaluation, and is used for bonding to the second chip 200. In a case where a plurality of first chips 100 are formed on the same wafer, the electrical performance evaluation is performed for each chip on the wafer, and the first chip 100 that is a non-defective product can be selected and used when each chip is cut later.

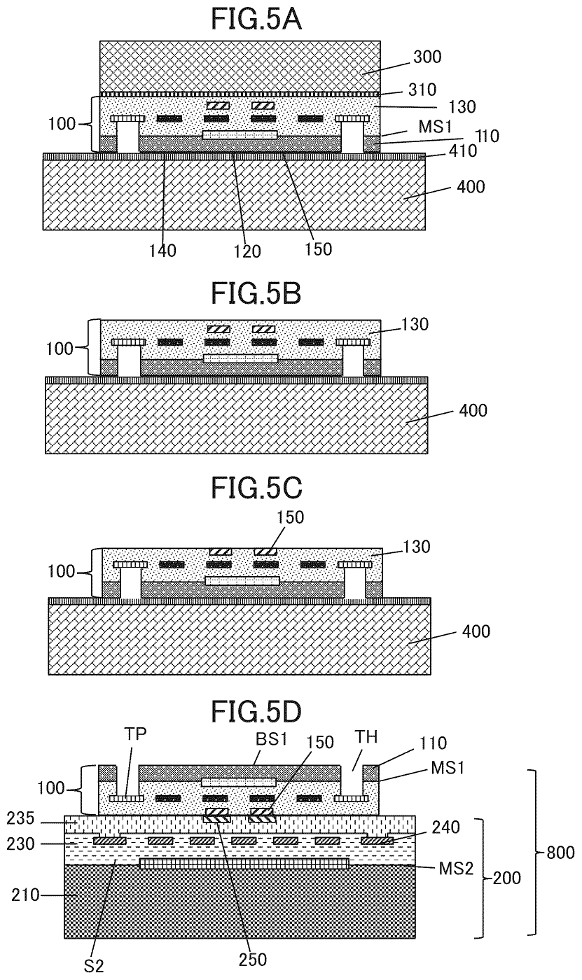

The first chip 100 in the form illustrated in FIG. 2A is not completed at the stage of FIG. 3E, and the subsequent processes will be described with reference to FIGS. 5A to 5C in the method for manufacturing the electronic device described below.

### Method for Manufacturing Second Chip

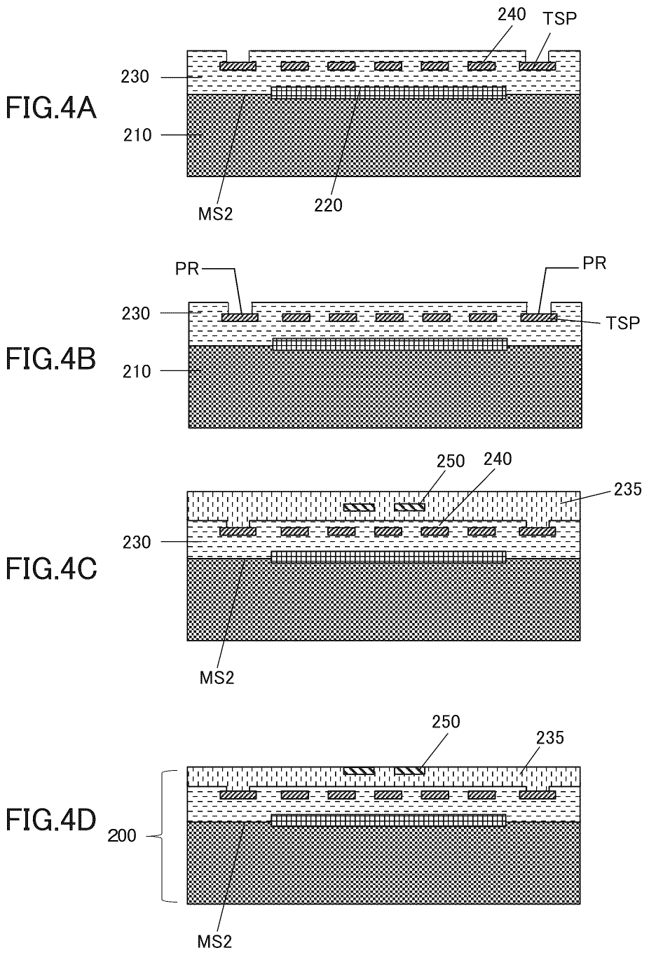

Next, a method for manufacturing the second chip 200 (second chip preparing step) will be described with reference to FIGS. 4A to 4D. Each drawing illustrates a schematic cross section of the second chip 200 at each stage of the manufacturing process. Although only a single second chip 200 is illustrated in FIGS. 4A to 4D, it is also possible to form a plurality of second chips 200 on the same wafer and cut the same wafer later.

As illustrated in FIG. 4A, the semiconductor element 220, the second insulating layer 230, and the second wiring layer 240 are sequentially formed on the main surface MS2 (second main surface) of the second substrate 210. As the second substrate 210, for example, a single crystal semiconductor substrate such as silicon substrate can be used.

The semiconductor element 220 such as a transistor or a diode is provided on the main surface MS2 which is one main surface of the second substrate 210. When an insulator substrate such as glass or resin is used for the second substrate 210 without using a semiconductor substrate, a thin film transistor (TFT) may be provided as the second semiconductor element 220 on the main surface MS2 of the insulator substrate.

The second insulating layer 230 is provided on the second semiconductor element 220 and on the main surface MS2 on which the second semiconductor element 220 is not provided. As the second insulating layer 230, for example, silicon oxide, silicon nitride, silicon oxynitride, silicon carbide, or the like is used. A contact plug (not illustrated) electrically connected to the second semiconductor element 220 is disposed in the second insulating layer 230. A conductive material such as tungsten is embedded in the contact plug. The second wiring layer 240 electrically connected to the semiconductor element 220 via the contact plug is provided inside the second insulating layer 230.

Although the second wiring layer 240 is schematically illustrated as a single layer in the drawing, the second wiring layer 240 may have a multilayer wiring structure in which a plurality of wiring layers is stacked. The second insulating layer 230 can function as an interlayer insulating layer in the multilayer wiring structure. The multilayer wiring structure may include vias and plugs that connect wiring of different layers. A metal material such as aluminum or copper is used for the second wiring layer 240, and a barrier metal such as Ti, Ta, TiN, or TaN may be provided at an interface between the second wiring layer 240 and the second insulating layer 230 in order to suppress diffusion of metal into the second insulating layer 230. In the second insulating layer 230, a test point TSP electrically connected to the second wiring layer 240 is provided, and a part of the second insulating layer 230 is removed such that the test point TSP is exposed.

Next, as illustrated in FIG. 4B, the probe PR of the tester is inserted into a hole where the test point TSP is exposed, and the probe PR is brought into contact with the test point TSP to evaluate electrical performance of the second chip 200. The second chip 200 that is a non-defective product is selected based on the electrical performance evaluation, and is used for bonding to the first chip 100. In a case where a plurality of second chips 200 are formed on the same wafer, the electrical performance evaluation is performed for each chip on the wafer, and the second chip 200 that is a non-defective product can be selected and used when each chip is cut later.

Next, as illustrated in FIG. 4C, a third insulating layer 235 is provided on the exposed test point TSP and the second insulating layer 230. By covering the test point TSP with which the probe PR is brought into contact, with the third insulating layer 235, corrosion of the second wiring layer 240 in a subsequent process or a small piece generated by contact with the probe PR is prevented from becoming a foreign matter and becoming a contamination source.

As the third insulating layer 235, similarly to the second insulating layer 230, silicon oxide, silicon nitride, or the like can be used. It is preferable to use the same type of insulating material as that of the first insulating layer 130 provided on the outermost surface of the first chip 100 as the third insulating layer 235 of the second chip 200, so that the first insulating layer 130 and the third insulating layer 235 can be easily and directly bonded. For example, in a case where silicon oxide is used as the first insulating layer 130, it is preferable to use silicon oxide having the same composition as the third insulating layer 235.

The second connection electrode 250 is provided inside the third insulating layer 235. The semiconductor element 220, the second wiring layer 240, and the second connection electrode 250 are electrically connected to form an electronic circuit. A dummy pattern that is not electrically connected to a circuit may be formed in the same layer as the second connection electrode 250, and the dummy pattern may be used as an anchor for enhancing a bonding strength when the first chip 100 and the second chip 200 are bonded.

Next, as illustrated in FIG. 4D, the third insulating layer 235 is polished by CMP, and the second connection electrode 250 is exposed, thereby completing the second chip 200. At this time, by polishing a step between the second connection electrode 250 and the third insulating layer 235 so as to be as flat as possible, it is possible to improve a yield when the first chip 100 and the second chip 200 are bonded.

In FIG. 4D, an insulating layer formed later is illustrated as the third insulating layer 235 to be distinguished from the second insulating layer 230, but in FIG. 2B referred to above, both insulating layers are illustrated collectively as the second insulating layer 230.

### Methods for Manufacturing Electronic Device and Electronic Component

A method for manufacturing the electronic device 800 by bonding the first chip 100 selected as a non-defective chip and the second chip 200 formed on the wafer, and a method for manufacturing the electronic component 900 by mounting the electronic device 800 on the circuit board 600 will be sequentially described.

First, the first chip 100 selected as a non-defective product by the process of FIG. 3E is bonded to a second carrier substrate 400 via a second temporary bonding layer 410. That is, as illustrated in FIG. 5A, the second carrier substrate 400 is bonded to a surface of the first chip 100 opposite to the surface to which the first carrier substrate 300 is bonded via the second temporary bonding layer 410. As the second temporary bonding layer 410, a heat-release type adhesive whose adhesion strength is reduced by heating is used, but in a case where a light-transmissive substrate is used as the second carrier substrate 400, a UV-release type adhesive whose adhesion strength is reduced by irradiation with ultraviolet rays may be used.

Next, as illustrated in FIG. 5B, heat or ultraviolet rays are applied to the first carrier substrate 300 to eliminate the adhesion strength of the first temporary bonding layer 310, and the first carrier substrate 300 is peeled off from the first chip 100 to expose the first insulating layer 130. In a case where the heat-release type adhesive is used for both the first temporary bonding layer 310 and the second temporary bonding layer 410, a heat-release type adhesive whose adhesion strength becomes lower at a higher temperature than that of the first temporary bonding layer 310 is used as the second temporary bonding layer 410. In this way, in a process of peeling off the first carrier substrate 300 by heat as illustrated in FIG. 5B, a decrease in adhesion strength of the second temporary bonding layer is suppressed, so that the first chip 100 is prevented from being peeled off from the second carrier substrate 400.

Next, as illustrated in FIG. 5C, the first insulating layer 130 is polished by CMP to expose the first connection electrode 150. As described above, after the first carrier substrate 300 is peeled off from the first chip 100, the first insulating layer 130 is polished to expose the first connection electrode 150, whereby the residue of the first temporary bonding layer 310 is removed from the surfaces of the first connection electrode 150 and the first insulating layer 130. Therefore, in a process of bonding the first chip 100 and the second chip 200 to be performed later, it is possible to suppress a decrease in yield due to the residue of the first temporary bonding layer 310. In addition, the above polishing is performed such that the step between the first connection electrode 150 and the first insulating layer 130 is polished so as to be as small as possible, so that the yield of the process of bonding the first chip 100 and the second chip 200 can be improved.

Next, as illustrated in FIG. 5D, the process of bonding the first chip 100 and the second chip 200 is performed. Here, an example of a direct bonding method is described, but bonding may be performed using a bump such as a solder bump or a micro bump. In this case, after the process of FIG. 5C, a bump member (not illustrated) is separately formed on the surface of any one of the first connection electrode 150 and the second connection electrode 250, and then the bonding is performed by melting the bump member.

In the case of directly bonding the first chip 100 and the second chip 200 formed on the wafer, first, the outermost surface of the first chip 100 is cleaned by two-fluid cleaning or spin cleaning using pure water to remove foreign matters attached to the surface. Next, the adhesion strength of the second temporary bonding layer 410 is eliminated to peel off the first chip 100 from the second carrier substrate 400. At this time, heat or ultraviolet rays are applied according to the type of the second temporary bonding layer 410. Thereafter, the main surface of the first chip 100 on the side where the first connection electrode 150 is exposed is irradiated with plasma, thereby activating the surface.

Similarly, the outermost surface of the second chip 200 formed on the wafer is cleaned by two-fluid cleaning or spin cleaning using pure water to remove foreign matters attached to the surface. Then, the main surface of the second chip 200 on the side where the second connection electrode 250 is exposed is irradiated with plasma, thereby activating the surface.

Once the surfaces of both the chips are cleaned and activated, the main surface of the first chip 100 (the main surface on the side where the first connection electrode 150 is provided) and the main surface of the second chip 200 (the main surface on the side where the second connection electrode 250 is provided) are quickly made to face each other, and the first connection electrode 150 and the second connection electrode 250 are aligned. Then, a load is applied from a surface BS1 in a state where the first connection electrode 150 and the second connection electrode 250, and the first insulating layer 130 and the third insulating layer 235 are in contact with each other. As a result, the first insulating layer 130 and the third insulating layer 235 are pressure-bonded at ambient temperature. Thereafter, a load is applied from the surface BS1 for a predetermined time while performing heating to about 250° C. to 400° C. As a result, the first connection electrode 150 and the second connection electrode 250 are bonded by thermal diffusion, thereby completing direct bonding (thermocompression bonding).

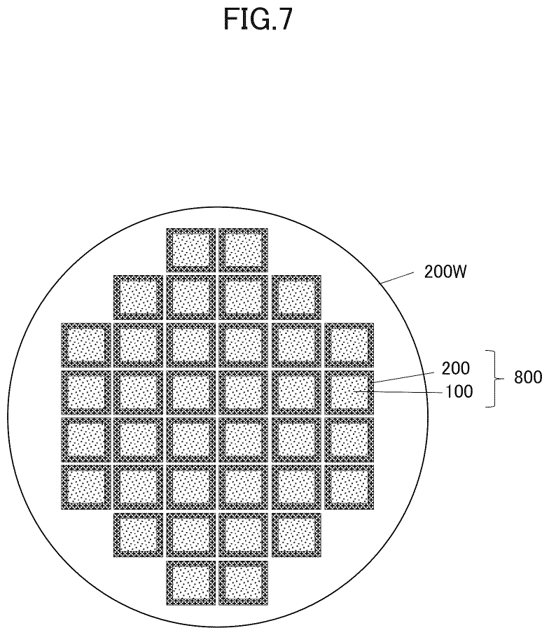

In the direct bonding process described above, the first chip 100 determined to be a non-defective product is aligned with and bonded to the second chip 200 determined to be a non-defective product among the second chips formed on the wafer. As a result, as illustrated in FIG. 7, a plurality of electronic devices 800 in which the non-defective first chips 100 are mounted on the non-defective second chips 200 are formed on a wafer 200W.

In the above example, the first chip 100 and the second chip 200 are bonded after the diced first chip 100 is peeled off from the second carrier substrate 400, but the bonding procedure is not limited thereto. The diced first chip 100 may be aligned with and bonded to the second chip 200 in a state where the second carrier substrate 400 is attached, and then the second carrier substrate 400 may be peeled off. In this case, after the first insulating layer 130 and the third insulating layer 235 are bonded at ambient temperature, the adhesion strength of the second temporary bonding layer 410 is eliminated by applying heat or ultraviolet rays, and the second carrier substrate 400 is peeled off. Thereafter, a load is applied from the surface BS1 of the first substrate 110 for a predetermined time while applying heat of about 250° C. to 400° C. to bond the first connection electrode 150 and the second connection electrode 250.

In particular, in a case where the thickness of the first chip 100 is decreased to a thickness of 200 μm or less, there is a possibility that an end portion or the like of the first chip 100 is damaged when the first chip 100 is conveyed to a predetermined position on the second chip 200. As the first chip 100 is conveyed in a state where the second carrier substrate 400 is attached, the possibility of damage can be reduced.

Furthermore, although not illustrated, in a case where the first chip 100 is a back-illuminated image sensor, color filters and microlenses are formed on a back surface (surface BS1) side of the first chip 100 after the process of FIG. 5D. As illustrated in FIG. 7, in a case where the first chips 100 are arranged at intervals on the wafer on which the second chips 200 are arranged in a matrix, there is a possibility that a step between the first chips 100 affects processing of a color filter or a microlens. In such a case, it is preferable that the interval between the first chips 100 is filled with a resin or silicon oxide to flatten the step, and then a color filter or a microlens is formed.

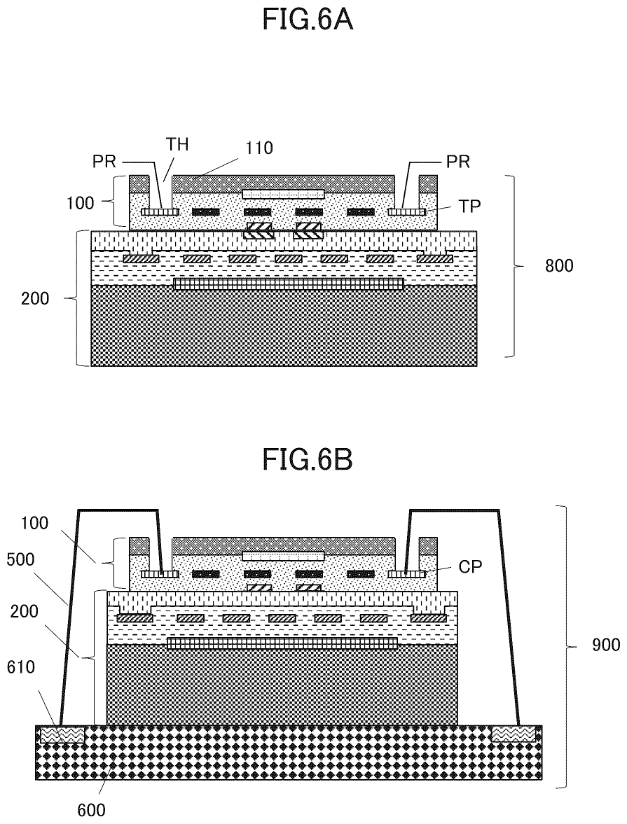

Next, as illustrated in FIG. 6A, the probe PR of the tester is brought into contact with the test terminal TP exposed through the through hole TH penetrating through the first substrate 110, and the electrical characteristic of the electronic device 800 is evaluated. That is, quality is determined for each of the plurality of electronic devices 800 formed on the wafer 200W illustrated in FIG. 7. The wafer 200W is cut by dicing or scribing, and the non-defective electronic device 800 can be taken out as an individual piece.

Then, as illustrated in FIG. 6B, the non-defective electronic device 800 is mounted on and electrically connected to the circuit board 600. FIG. 6B illustrates an example in which a portion used as the test terminal TP in the process of FIG. 6A is also used as the external connection terminal CP of the first wiring layer 140, and the external connection terminal CP is electrically connected to an electrode 610 of the circuit board 600 by the connection member 500. In this way, the electronic component 900 according to the embodiment is completed.

### Second Embodiment

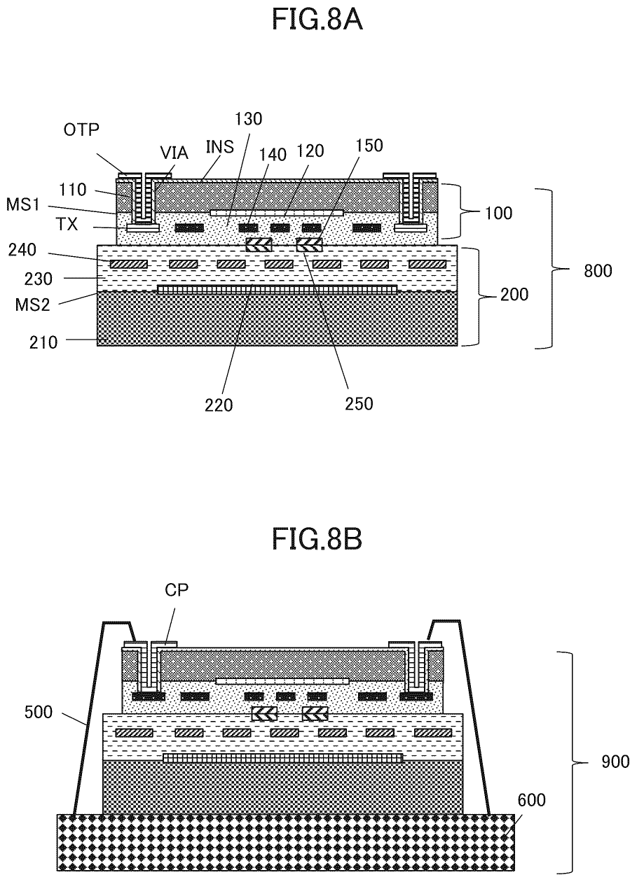

An electronic device (semiconductor apparatus) and an electronic component according to a second embodiment will be described with reference to the drawings, but a description of matters common to the first embodiment will be simplified or omitted. FIG. 8A is a schematic cross-sectional view of an electronic device 800 according to the second embodiment taken along a direction orthogonal to a main surface.

In the first embodiment, the semiconductor element 120, the first insulating layer 130, the first wiring layer 140, the test terminal TP, and the first connection electrode 150 are provided on the main surface MS1 of the substrate 110 of the first chip 100. Then, the through hole penetrating through the first substrate 110 is provided, and the through hole further extends into the first insulating layer 130 to expose the test terminal TP. Then, the probe of the tester can externally access (contact) the test terminal TP through the through hole.

As illustrated in FIG. 8A, the second embodiment is the same as the first embodiment in that a semiconductor element 120, a first insulating layer 130, a first wiring layer 140, and a first connection electrode 150 are provided on a main surface MS1 of a substrate 110 of a first chip 100. However, instead of providing a test terminal TP by exposing a point to be tested in the same layer as the first wiring layer 140 as in the first embodiment, a test terminal OTP is provided on an outer surface of the substrate 110 that is opposite to the main surface MS1. When the point to be electrically tested in the first wiring layer 140 is a point TX, the test terminal OTP is electrically connected to the point TX through a via VIA.

An insulating layer INS such as silicon oxide is provided between the test terminal OTP and the first substrate 110. Similarly to the first wiring layer 140, aluminum or copper is used as a material of the test terminal OTP, and a barrier metal such as Ti, Ta, TiN, or TaN may be provided at an interface between the test terminal OTP and the insulating layer INS.

In order to manufacture such a structure, for example, after processes similar to those in FIGS. 3A to 3D described in the first embodiment are performed, an insulating film such as silicon oxide is formed on a side surface of a through hole TH and the outer surface of the first substrate 110 (a main surface opposite to the main surface MS1). Then, the side surface of the through hole TH is covered with a conductive material by a technique such as sputtering or plating to form the via VIA. The test terminal OTP on the outer surface of the first substrate 110 and the point TX are electrically connected by the via VIA. In some cases, the inside of the formed via VIA may be filled with an insulating member (not illustrated) such as a resin to suppress deterioration of a first semiconductor element 120 due to intrusion of moisture or a chemical substance.

Also in the electronic device 800 according to the present embodiment, as illustrated in FIG. 1A, a projected area of a first chip 100 in which the test terminal OTP is provided can be made smaller than a projected area of a second chip 200 in plan view, so that the cost of the substrate can be reduced. Moreover, the first chip 100 is included in the second chip 200 in plan view, and both chips are arranged such that the first chip 100 does not protrude beyond the outer edge of the second chip 200. In the electronic device 800 according to the present embodiment, it is possible to easily access the test terminal OTP provided on the surface opposite to the main surface MS1 (the main surface on a side on which the semiconductor element 120 is provided) of the first substrate 110. As described above, according to the present embodiment, when the first chip 100 including the test terminal and the second chip 200 are arranged and integrated such that the semiconductor elements face each other, size reduction of the electronic device 800 can be achieved.

In addition, according to the present embodiment, since the test terminal OTP is formed on the outer surface of the first substrate 110, a probe of a tester can be easily brought into contact with the test terminal OTP when evaluating an electrical characteristic, and damage to the first insulating layer 130 can be suppressed as compared with the first embodiment.

Then, as illustrated in FIG. 8B, the non-defective electronic device 800 is mounted on and electrically connected to a circuit board 600. FIG. 8B illustrates an example in which a portion used as the test terminal OTP in the electrical characteristic evaluation is also used as an external connection terminal CP, and the external connection terminal CP is electrically connected to an electrode of the circuit board 600 by a connection member 500. In this way, an electronic component 900 according to the present embodiment is completed.

### Third Embodiment

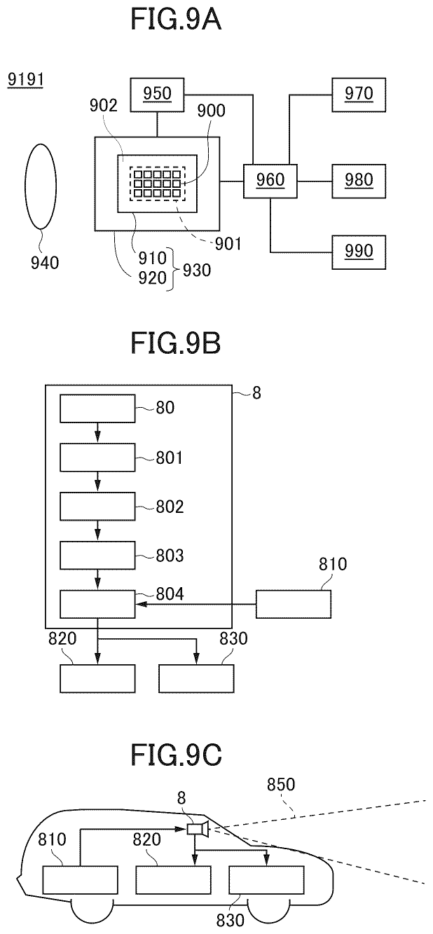

As a third embodiment, a system including an electronic device in which a first chip 100 is an image sensor and a second chip 200 is a chip including at least one of a memory circuit and a logic circuit will be described. FIG. 9A is a schematic diagram for describing equipment 9191 including a semiconductor apparatus 930 including the electronic device according to the above-described embodiment. The equipment 9191 including the semiconductor apparatus 930 will be described in detail.

The semiconductor apparatus 930 includes a semiconductor device 910 in which the first chip serving as a photoelectric conversion apparatus and the second chip including at least one of a memory circuit and a logic circuit are integrated. In addition to the semiconductor device 910, the semiconductor apparatus 930 may include a package 920 that houses the semiconductor device 910. The package 920 can include a base to which the semiconductor device 910 is fixed, and a lid made of glass or the like and facing the semiconductor device 910. The package 920 can further include a bonding member such as a bonding wire or a bump that connects a terminal provided on the base and a terminal provided on the semiconductor device 910.

The equipment 9191 can include at least one of an optical apparatus 940, a control apparatus 950, a processing apparatus 960, a display apparatus 970, a storage apparatus 980, and a mechanical apparatus 990. The optical apparatus 940 is, for example, a lens, a shutter, or a mirror provided corresponding to the semiconductor apparatus 930. The control apparatus 950 controls the semiconductor apparatus 930. The control apparatus 950 is, for example, a semiconductor apparatus such as an application specific integrated circuit (ASIC).

The processing apparatus 960 processes a signal output from the semiconductor apparatus 930. The processing apparatus 960 is a semiconductor apparatus such as a central processing unit (CPU) or an ASIC for configuring an analog front end (AFE) or a digital front end (DFE). The display apparatus 970 is an EL display device or a liquid crystal display device that displays information (image) obtained by the semiconductor apparatus 930. The storage apparatus 980 is a magnetic device or a semiconductor device that stores information (image) obtained by the semiconductor apparatus 930. The storage apparatus 980 is a volatile memory such as a static random-access memory (SRAM) or a dynamic random-access memory (DRAM), or a nonvolatile memory such as a flash memory or a hard disk drive.

The mechanical apparatus 990 includes a movable unit such as a motor or an engine, or a propulsion unit. In the equipment 9191, a signal output from the semiconductor apparatus 930 is displayed on the display apparatus 970, or is transmitted to the outside by a communication apparatus (not illustrated) included in the equipment 9191. Therefore, the equipment 9191 preferably further includes the storage apparatus 980 and the processing apparatus 960 separately from a storage circuit and an arithmetic circuit of the semiconductor apparatus 930. The mechanical apparatus 990 may be controlled based on a signal output from the semiconductor apparatus 930.

Furthermore, the equipment 9191 is suitable for an electronic device such as an information terminal (for example, a smartphone or a wearable terminal) having an imaging function or a camera (for example, an interchangeable lens camera, a compact camera, a video camera, or a surveillance camera). The mechanical apparatus 990 in the camera can drive components of the optical apparatus 940 for zooming, focusing, and shutter operations. Alternatively, the mechanical apparatus 990 in the camera can move the semiconductor apparatus 930 for vibration-proof operation.

Furthermore, the equipment 9191 can be transportation equipment such as a vehicle, a ship, or a flying object. The mechanical apparatus 990 in transportation equipment can be used as a mobile apparatus. The equipment 9191 serving as the transportation equipment is suitable for transporting the semiconductor apparatus 930 and assisting and/or automating driving (steering) by the imaging function. The processing apparatus 960 for assisting and/or automating driving (steering) can perform processing for operating the mechanical apparatus 990 serving as the mobile apparatus based on information obtained by the semiconductor apparatus 930. Alternatively, the equipment 9191 may be medical equipment such as an endoscope, measurement equipment such as a distance measuring sensor, analysis equipment such as an electron microscope, office equipment such as a copying machine, or industrial equipment such as a robot.

According to the embodiment described above, a non-defective chip whose characteristics have been inspected using the test terminal is used, and thus, it is possible to acquire an image having a favorable characteristic, and it is possible to reduce a size and weight of the apparatus.

Therefore, when the semiconductor apparatus 930 according to the present embodiment is used for the equipment 9191, the value of the equipment can also be improved. For example, it is possible to obtain excellent performance when the semiconductor apparatus 930 is mounted on the transportation equipment to image the outside of the transportation equipment or measure an external environment. Therefore, in manufacturing and selling the transportation equipment, it is advantageous to determine to mount the semiconductor apparatus according to the present embodiment on the transportation equipment in terms of enhancing the performance of the transportation equipment itself. In particular, the semiconductor apparatus 930 is suitable for driving assistance of the transportation equipment and/or transportation equipment that performs automated driving using information obtained by the semiconductor apparatus. Implementation in a vehicle, a ship, a flying object, or the like is not limited to application to equipment practically used for transportation purposes, and can be suitably made in, for example, a drone or the like that performs aerial imaging for various purposes including inspection of buildings and agricultural facilities, monitoring of natural phenomena, and the like.

A photoelectric conversion system and a mobile body according to the present embodiment will be described with reference to FIGS. 9B and 9C.

FIG. 9B illustrates an example of the photoelectric conversion system related to an in-vehicle camera. A photoelectric conversion system 8 includes a photoelectric conversion apparatus 80. The photoelectric conversion apparatus 80 is a photoelectric conversion apparatus serving as the electronic device described in the above embodiment. The photoelectric conversion system 8 includes an image processing unit 801 that performs image processing on a plurality of pieces of image data acquired by the photoelectric conversion apparatus 80, and a parallax acquisition unit 802 that calculates a parallax (a phase difference of a parallax image) from the plurality of pieces of image data acquired by the photoelectric conversion system 8. Furthermore, the photoelectric conversion system 8 includes a distance acquisition unit 803 that calculates a distance to a target object based on the calculated parallax, and a collision determination unit 804 that determines whether or not there is a possibility of collision based on the calculated distance. Here, the parallax acquisition unit 802 and the distance acquisition unit 803 are examples of a distance information acquisition unit that acquires distance information to the target object. That is, the distance information is information regarding the parallax, a defocus amount, the distance to the target object, and the like. The collision determination unit 804 may determine the possibility of collision by using any one of these pieces of distance information. The distance information acquisition unit may be implemented by dedicated hardware or may be implemented by a software module. In addition, the distance information acquisition unit may be implemented by a field programmable gate array (FPGA), an application specific integrated circuit (ASIC), or the like.

The photoelectric conversion system 8 is connected to a vehicle information acquisition apparatus 810, and can acquire vehicle information such as a vehicle speed, a yaw rate, and a steering angle. In addition, the photoelectric conversion system 8 is connected to a control ECU 820 which is a control apparatus that outputs a control signal for generating a braking force for the vehicle based on a determination result of the collision determination unit 804. The photoelectric conversion system 8 is also connected to a warning apparatus 830 that alerts a driver based on the determination result of the collision determination unit 804. For example, in a case where the possibility of collision indicated by the determination result of the collision determination unit 804 is high, the control ECU 820 performs vehicle control to avoid collision and reduce damage by applying a brake, releasing an accelerator, reducing engine output, or the like. The warning apparatus 830 alerts a user by emitting an audible alarm or the like, displaying warning information on a screen of a car navigation system or the like, applying vibration to a seat belt or a steering wheel, or the like.

In the present embodiment, the periphery of the vehicle, for example, an area in front of or behind the vehicle is imaged by the photoelectric conversion system 8.

FIG. 9C illustrates the photoelectric conversion system in the case of imaging the area in front of the vehicle (imaging range 850). The vehicle information acquisition apparatus 810 transmits an instruction to the photoelectric conversion system 8 or the photoelectric conversion apparatus 80. With such a configuration, accuracy of distance measurement can be further improved.

In the above description, an example of performing control so as not to collide with another vehicle has been described, but the present technology is also applicable to control of performing automated driving following another vehicle, control of performing automated driving so as not to stray from a lane, and the like. Furthermore, the photoelectric conversion system is not limited to a vehicle such as an own vehicle, and can be applied to a mobile body (mobile apparatus) such as a ship, an aircraft, or an industrial robot, for example. In addition, the present technology can be applied not only to a mobile body but also to equipment that widely uses object recognition, such as an intelligent transport system (ITS). According to the embodiment described above, a non-defective chip whose characteristics have been inspected using the test terminal is used, and thus, it is possible to acquire a good image, and moreover, the apparatus can be reduced in size and weight and thus is suitable for being mounted on a mobile body.

### Other Embodiments

Note that the present invention is not limited to the embodiments described above, and many modifications can be made within the technical idea of the present invention. For example, all or some of the different embodiments described above may be combined and implemented.

For example, in the above-described embodiments, one first chip having a small projected area is mounted so as to be included in the second chip having a large projected area in plan view, but the number of chips mounted on the second chip does not have to be one as long as the chips are included in the second chip in plan view. In each chip mounted on the second chip, if the terminal electrically connected to the first wiring layer is exposed on the side opposite to the second chip, the same effects as that of the above-described embodiments can be obtained.

The photoelectric conversion apparatus to which the present invention is applied is not limited to a specific form, and for example, a light receiving unit may be any one of a front-illuminated type or a back-illuminated type. An image signal output from the photoelectric conversion apparatus may be an analog signal or a digital signal. Furthermore, the application of the photoelectric conversion apparatus according to the embodiment is not limited to imaging, and can also be applied to, for example, a distance measuring apparatus (an apparatus for focus detection, distance measurement using a time of flight (TOF), or the like) and a photometric apparatus (an apparatus for measuring the amount of incident light, or the like).

According to the present disclosure, it is possible to suppress an increase in size of an electronic device (semiconductor apparatus) while installing a test terminal for evaluating an electrical characteristic for the electronic device (semiconductor apparatus) formed by bonding surfaces of respective chips on which semiconductor elements are formed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-199494, filed Nov. 24, 2023, which is hereby incorporated by reference herein in its entirety.

What is claimed is:

1. An electronic device comprising:
a first chip in which a first semiconductor element, a first insulating layer, a first wiring layer, and a first connection electrode formed in a layer different from the first wiring layer are provided on a side of a first main surface of a first substrate; and
a second chip in which a second semiconductor element, a second insulating layer, a second wiring layer, and a second connection electrode formed in a layer different from the second wiring layer are provided on a side of a second main surface of a second substrate, wherein
the first chip and the second chip are fixed such that the first main surface and the second main surface face each other with the first insulating layer, the first wiring layer, the first connection electrode, the second insulating layer, the second wiring layer, and the second connection electrode interposed therebetween, and the first connection electrode and the second connection electrode are electrically connected,
the first chip includes a terminal electrically connected to the first wiring layer and exposed to a side opposite to the second chip, and
a projected area of the first chip is smaller than a projected area of the second chip, and the first chip is included in the second chip in plan view in a case where viewed from a direction perpendicular to the first main surface.

2. The electronic device according to claim 1, wherein the terminal is provided in the same layer as the first wiring layer, and is exposed to the side opposite to the second chip through a through hole penetrating through the first substrate and a part of the first insulating layer.

3. The electronic device according to claim 1, wherein the terminal is provided on a main surface of the first substrate that is opposite to the first main surface, and is electrically connected to the first wiring layer via a conductive material provided in a through hole penetrating through the first substrate and a part of the first insulating layer.

4. The electronic device according to claim 1, wherein the first insulating layer and the second insulating layer are bonded.

5. The electronic device according to claim 1, wherein the first insulating layer and the second insulating layer are made of the same type of insulating material.

6. The electronic device according to claim 1, wherein the first connection electrode and the second connection electrode are bonded.

7. The electronic device according to claim 1, wherein the terminal is provided to test an electrical characteristic of the first chip.

8. The electronic device according to claim 1, wherein the first chip is a chip including an image sensor, and the second chip is a chip including at least one of a memory circuit and a logic circuit.

9. The electronic device according to claim 8, wherein the image sensor is a back-illuminated image sensor, and at least one of a color filter and a microlens is provided on a main surface of the first substrate that is opposite to the first main surface.

10. The electronic device according to claim 1, wherein a plurality of second chips, each of which is the second chip, is provided on the same wafer.

11. An electronic component comprising:
the electronic device according to claim 1; and
a circuit board on which the electronic device is mounted,
wherein the terminal and the circuit board are electrically connected.

12. A method for manufacturing an electronic device, the method comprising:
a first chip preparing step of preparing a first chip in which a first semiconductor element, a first insulating layer, a first wiring layer, and a first connection electrode formed in a layer different from the first wiring layer are provided on a side of a first main surface of a first substrate, and a terminal electrically connected to the first wiring layer is exposed to a side opposite to the first main surface;
a second chip preparing step of preparing a second chip in which a second semiconductor element, a second insulating layer, a second wiring layer, and a second connection electrode formed in a layer different from the second wiring layer are provided on a side of a second main surface of a second substrate; and
a fixing step of fixing the first chip and the second chip such that the first main surface and the second main surface face each other with the first insulating layer, the first wiring layer, the first connection electrode, the second insulating layer, the second wiring layer, and the second connection electrode interposed therebetween, the first connection electrode and the second connection electrode are electrically connected, and a projected area of the first chip is smaller than a projected area of the second chip, and the first chip is included in the second chip in plan view in a case where viewed from a direction perpendicular to the first main surface.

13. The method for manufacturing the electronic device according to claim 12, wherein
in the first chip preparing step,
after forming the first semiconductor element, the first insulating layer, the first wiring layer, and the first connection electrode on the side of the first main surface of the first substrate,
a through hole that penetrates through the first substrate and a part of the first insulating layer and extends to a part of the first wiring layer is formed, and the terminal is formed by exposing a part of the first wiring layer.

14. The method for manufacturing the electronic device according to claim 12, wherein
in the first chip preparing step,
after forming the first semiconductor element, the first insulating layer, the first wiring layer, and the first connection electrode on the side of the first main surface of the first substrate,
a through hole that penetrates through the first substrate and a part of the first insulating layer and extends to a part of the first wiring layer is formed, a conductive material is provided along the through hole, and the terminal electrically connected to the conductive material is provided on a main surface of the first substrate that is opposite to the first main surface.

15. The method for manufacturing the electronic device according to claim 12, wherein in the fixing step, the first connection electrode and the second connection electrode are bonded by thermocompression bonding.

16. The method for manufacturing the electronic device according to claim 12, wherein in the fixing step, the first insulating layer and the second insulating layer are pressure-bonded at ambient temperature.

17. The method for manufacturing the electronic device according to claim 12, wherein
in the first chip preparing step,
a probe of a tester is brought into contact with the terminal to test an electrical characteristic of the first chip.

18. The method for manufacturing the electronic device according to claim 17, wherein the first chip determined to be a non-defective product by the test is fixed to the second chip in the fixing step.

19. The method for manufacturing the electronic device according to claim 12, wherein
in the second chip preparing step,
a plurality of second chips, each of which is the second chip, is provided on the same wafer.

20. The method for manufacturing the electronic device according to claim 19, wherein
in the second chip preparing step,
an electrical characteristic of the plurality of second chips provided on the same wafer is tested, and
the second chip determined to be a non-defective product by the test is fixed to the first chip in the fixing step.

21. The method for manufacturing the electronic device according to claim 12, wherein after the fixing step, a probe of a tester is brought into contact with the terminal to test an electrical characteristic of the electronic device.

22. A method for manufacturing an electronic component, the method comprising:
manufacturing the electronic device by the method for manufacturing the electronic device according to claim 12;
mounting the electronic device on a circuit board; and
electrically connecting the terminal and the circuit board.
